(19) United States
(12) Patent Application Publication
(10) Pub. No.: US 2007/0182503 A1
(43) Pub. Date: Aug. 9, 2007

(54) Oscillator having low phase noise

(75) Inventor: Joseph G. Petrofsky, Los Gatos, CA (US)

Correspondence Address: MCDERMOTT WILL & EMERY LLP, 600 13TH STREET, N.W., WASHINGTON, DC, 20005-3096, US

(73) Assignee: LINEAR TECHNOLOGY CORPORATION

(21) Appl. No.: 11/348,354

(22) Filed: Feb. 7, 2006

(51) Int. Cl. H03L 7/099

(52) U.S. Cl. 331/185

(57) ABSTRACT

An oscillator for minimizing phase noise is configured with a transistor coupled to a first reference voltage source, a differential transistor pair comprising first and second voltage followers coupled between a second reference voltage source and the transistor, and a reactive network coupled between control electrodes of the first and second voltage followers. A resistance network is coupled between the control electrodes and in parallel with the reactive network. Various embodiments, including Colpitts and Clapp, are presented.

### FIELD OF THE INVENTION

This disclosure relates to oscillators, particularly oscillators having novel circuit implementations to minimize phase noise and achieve other functional improvements.

### BACKGROUND

There is need in a wide variety of electronic equipment, particularly communication and instrumentation equipment, for a low phase noise time reference. This is so because any signal that is translated in frequency (via mixing) or sampled in time (such as analog-to-digital conversion) will be corrupted if there is excess phase noise on the timing signal used.

A voltage controlled oscillator (VCO) is a useful building block for designing such equipment. The VCO creates a timing signal, which can be thought of as a frequency source or a timing clock, two ways of expressing the same concept. The VCO also provides means to control frequency. This means is useful in building phase-locked-loops (PLLs) which have many applications including frequency multiplication, synchronizing multiple frequency sources, demodulating FM signals, among others.

Any VCO tends to have timing imperfections that produce an output timing clock signal having periods that may not be all identical. These imperfections can be considered to cause timing jitter, usually referred to as phase noise for high performance designs.

The phase noise of oscillators, including VCOs, has been studied extensively. An overview of the field was summarized in “Oscillator Phase Noise: A Tutorial”, by T. Lee and A. Hajimiri in the IEEE JSSCC, Vol 35, #3, pp 326-336, March 2000, incorporated herein by reference.

Of the wide variety of oscillator types, including inverter rings, relaxation, and Wein-Bridge, LC oscillators are well recognized to have low phase-noise. The name comes from a resonator combination of an inductor (L) and a capacitor (C), but any low-loss resonator is in general suitable for use in an LC oscillator topology. Other resonators include quartz crystals, ceramic resonators, tuned cavities, and distributed strip-line networks. Quartz and ceramic resonators have higher quality factors (Q). However, because their electro-mechanical resonances include two energy storage elements—the inductor and capacitor in an electrical model, or the spring and mass in a mechanical model, their use in VCOs is limited as one of the two energy storage elements must be adjusted to provide frequency control. Hollow cavities and strip-line networks also include a complete frequency-setting structure, and are generally used only in exotic VCOs for specialized applications.

FIG. 1 illustrates the fundamental model of LC oscillators, in which a resonator consisting of inductor L10 and capacitor C10 are shown in parallel with resistor R10 which models the losses in the resonator. An active circuit drives the resonator to oscillate by presenting a synthetic negative resistance −R in parallel with the resonator.

To improve phase noise performance, a resonator with as high a Q as possible should be used. This results in as large resistor R as possible, which contributes minimal noise in a parallel resonator model. This also means that the active circuit needs the lowest current drive possible for a given tank energy level, which also minimizes noise generation by the active circuit that results in phase noise.

The literature is filled with examples of LC oscillators using resonators constructed entirely on-chip, but these suffer from the poor Q of inductors due to both series resistance of metal windings and losses in a silicon substrate. These oscillators are generally limited to at least 750 MHz and above because below that frequency, resonator elements, particularly an inductor, become too large. Thus, for optimal phase-noise performance, it is preferable to use a discrete off-chip inductor. Off-chip components are relatively inexpensive, and are readily available today with tight tolerances, ±2%, and a Q well above 100.

One oscillator using a discrete LC resonator is shown in FIG. 2. To accommodate a variety of tank impedances and Qs, the tail current of a differential pair of transistors Q10L, Q10R driving a tank comprising inductor L12 and capacitor C12 is varied. This circuit senses the voltage in a soft peak detector comprising tank buffer transistor Q12 and feedback devices including transistor Q14 and resistor R12. The emitter of transistor Q12 is grounded through resistor R18. External capacitor C14 is coupled to the collector of transistor Q14 to filter out variations in the voltage at the tank frequency which would lead to undesirable distortions of the oscillator operation. An amplitude control loop is completed with resistor R14, diode D1, resistor R16 and transistor Q16. The amplitude control loop increases the tail current of the differential pair when the tank voltage is too low, and decreases the tail current when the tank voltage is too high. This circuit requires a DC current path from node Bias to node Tank. The DC bias is provided by resistor R20 and transistors Q18, Q20.

Another oscillator with a discrete LC resonator is described in M. Margarit et. al. in “A Low-Noise, Low-Power VCO with Automatic Amplitude Control for Wireless Applications”, IEEE JSSCC, Vol 34, #6, pp 761-771, June 1999, incorporated herein by reference. The core of the oscillator is shown in FIG. 3. The resonator comprises inductors L14, L16 and capacitor C14 external to an IC, and parallel-series combinations of on-chip capacitors C16, C18, C20 and C22. This is a balanced differential oscillator with a differential pair of transistors Q22L, Q22R actively driving a tank including inductors L14, L16 and capacitor C14. The bases of transistors Q22L, Q22R are connected to voltage source VS through resistors R22, R24, respectively. Due to variations in resonator Qs and impedances, the tail current of the differential pair must be actively varied.

In this circuit, there is a differential peak detector including transistors Q24L, Q24R. The bases of the transistors are coupled to the tank through coupling capacitors C26, C28, and coupled to resistors R34, R36, respectively. There is another differential pair of transistors Q28L, Q28R, the bases of which are coupled to resistors R38, R40, respectively.

Error amplifier EA2 is provided to control the tank voltage. The inverted input of error amplifier EA 2 is coupled to the differential pair of transistors Q24L, Q24R through resistors R26, R42 and capacitors C30, C32. The non-inverted input of the amplifier is coupled to the differential pair of transistors Q28L, Q28R through resistor R28. Currents I1 and I2 or resistors R26 and R28 are imbalanced such that error amplifier EA2 is satisfied only when the tank voltage peaks are at the appropriate level. To achieve this state, error amplifier EA2 drives transistor Q26, via a low pass filter comprising resistor R30 and capacitor C24.

Both of the oscillators shown in FIGS. 2 and 3 have excessive phase noise due to the configurations selected. The circuit of FIG. 2 runs out of headroom in transistor Q10L when the tank voltage exceeds a few hundred millivolts (mV) after which the transistor will saturate. The phase noise of an oscillator is limited by the tank energy, so this presents a topological phase noise limitation even if the transistors themselves are capable of operating at much higher voltages.

Another limitation of the circuit of FIG. 2 is that while the noise of the peak detector (transistors Q12 and Q14) will be filtered by capacitor C14 on node AGC, the noise contributions of diode D1, resistor R16 and transistor Q16 are not filtered. These devices are strictly bias devices, but with this topology, they can be significant contributors to phase noise.

The circuit of FIG. 3 suffers from similar limitations. Transistor Q26, a bias device, can be a significant contributor to phase noise. At least in this case, filter capacitor C24 is directly on the base of transistor Q26, and transistor Q26 is degenerated by resistor R32. However, the circuit of FIG. 3 still suffers from excessive phase noise because the tank energy is limited to a few hundred millivolts of voltage swing by the headroom required for transistors Q24L, Q24R.

Another circuit is a Colpitts oscillator. This versatile topology has recently been the subject of research in its differential form, such as in “The Effect of Varactor Non-Linearity on Phase Noise of Completely Integrated VCOs”, by J. Rogers et. al. in the IEEE JSSCC, Vol 35, #9, pp 1360-1367, September 2000, incorporated herein by reference. The oscillator core reported therein is shown in FIG. 4. The topology is a differential common-base form of the Colpitts oscillator, including a differential pair of transistors Q30L, Q30R, and a tank of inductors L18, L20 and capacitors C34, C36, C38. Node n10 is connected to a positive power supply node and ground node through resistors R48, R52. Node n 12 is coupled to the positive power supply node through resistor R50. Capacitor C34 is a combination of fixed capacitors and variable capacitance varactors. Because this design is implemented entirely on one chip, the resonator Q is low, but known and repeatable. Therefore there was no need for an amplitude stabilization loop. The bias currents I3/I4 are set to the proper levels for a desired tank energy level.

Rogers et. al. reports admirable phase noise with this topology given the resonator Q limitations of on-chip inductors L18, L20. However, this topology would not be suitable for lower frequencies. The larger inductor values would not be practical on-chip. With off-chip inductors, two problems arise. The first is that the amplitude varies substantially with the inductor Q. If it is too low, the tank energy is low and phase noise suffers. If the Q is too high, the tank energy increases to the point where transistors saturate or suffer voltage breakdown, both of which are detrimental to the functioning of the VCO, let alone the phase noise. A second problem with external inductors is that the coupling of the two inductors plays a role in setting the frequency of a differential oscillator. On-chip, their coupling is repeatable, and hence, this is not an issue. Another way to make the inductor coupling repeatable is to manufacture a resonator as a single unit, but this is a non-standard device and as such tends to be uneconomical for most applications.

Another type of device having modified Colpitts configuration, implements varactor and feedback capacitors integrated on-chip so that only an external inductor is required to establish the frequency of operation. Tuning range, biasing, startup, etc., are all managed internally. However, this type of device suffers from disadvantages in that (1) when standard values of inductors are used, two inductors are needed for those frequencies that a single standard value does not cover, and (2) the Clapp extension of the Colpitts configuration, described below, cannot be used. Although the second inductor can be a smaller value and have a lower Q, two inductors are still problematic. The second inductor would almost always be more expensive than a capacitor of similar Q if it were possible to use a capacitor to center the design. There is also the issue of the two inductors coupling to each other, which either raise or lower their effective inductance relative to the sums of their inductances depending on whether the coupling fields are constructively or destructively interfering with each other.

The Clapp extension of the Colpitts oscillator is a well-known topology described, for instance, by U. L. Rhode et. al., Communications Receivers, 2^{nd} Edition, McGraw-Hill publishing co., pp 413-419, incorporated herein by reference. The Clapp extension is simply a way to increase the tank energy in a Colpitts topology without imposing any additional voltage limitation on the circuit elements that are not part of the tank. FIGS. 5A and 5B show a generic topology of Colpitts and Clapp oscillators, respectively. The biasing is not shown, and one of the three transistor terminals is usually grounded at least for AC signals, but any of the three can be used in either oscillator type, and do not change the analysis here.

The Colpitts oscillator of FIG. 5A may, for instance, have inductor L22 of 10 nH, and capacitors C40 and C42 of 500 pF and 125 pF, respectively. The series combination of capacitor C40 and C42 will present 100 pF across the inductor, for a time constant of 1 nsec and a natural frequency of 159.1 MHz. The energy level of the tank is set by the 10Ω characteristic impedance of the resonator and the voltage level at which the oscillation stabilizes, either because of fixed or adjustable biasing of transistor Q32.

By comparison, the Clapp oscillator of FIG. 5B when made with inductor L24 of 20 nH, and capacitors C44, C46 and C48 of 500 pF, 125 pF, and 100 pF, respectively, also has a natural frequency of 159.1 MHz. However, if the voltages on transistor Q34 are stabilized to the same levels as for the circuit shown FIG. 5A, the tank energy becomes twice as large. The same (AC) current flows through capacitors C44 and C46 because the same voltages appear across them, but inductor L24 now creates twice as much voltage so that the same voltage is also created by that current across capacitor C48.

This Clapp extension, therefore, increases the tank energy for lower phase noise. This extension also increases the value of the inductor so that stray inductances in the loop have less impact. The addition of a third capacitor also provides a means for adjusting the frequency to accommodate a standard value inductor.

Therefore, there is a need for an integrated low phase noise voltage controlled oscillator operable with a single off-chip inductor, or with an off-chip inductor-capacitor combination, to overcome the limitations of the prior art. There is a further need for an integrated low phase noise voltage controlled oscillator with a low noise and/or large amplitude automatic gain control to overcome the limitations of the prior art.

### BRIEF DESCRIPTION OF THE DRAWINGS

Examples of the subject matter claimed herein are illustrated in the figures of the accompanying drawings and in which reference numerals refer to similar elements and in which:

FIG. 1 is a fundamental model of a schematic circuit topology of an LC oscillator.

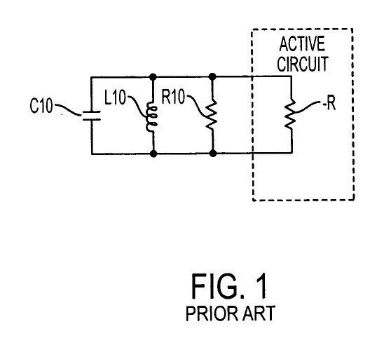

FIG. 2 is an example of a schematic circuit topology of an oscillator including a discrete LC resonator.

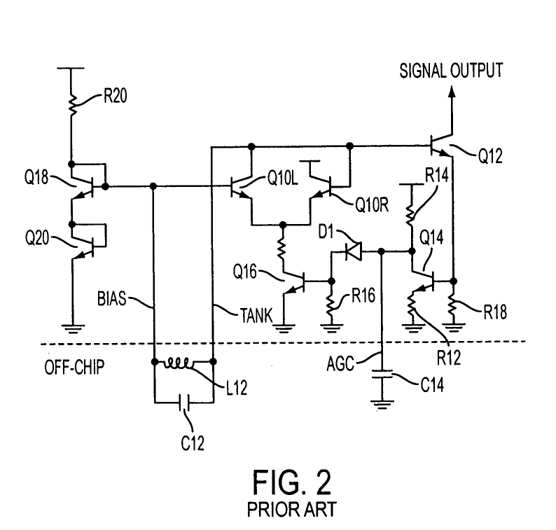

FIG. 3 is another example of a schematic circuit topology of an oscillator including a discrete LC resonator.

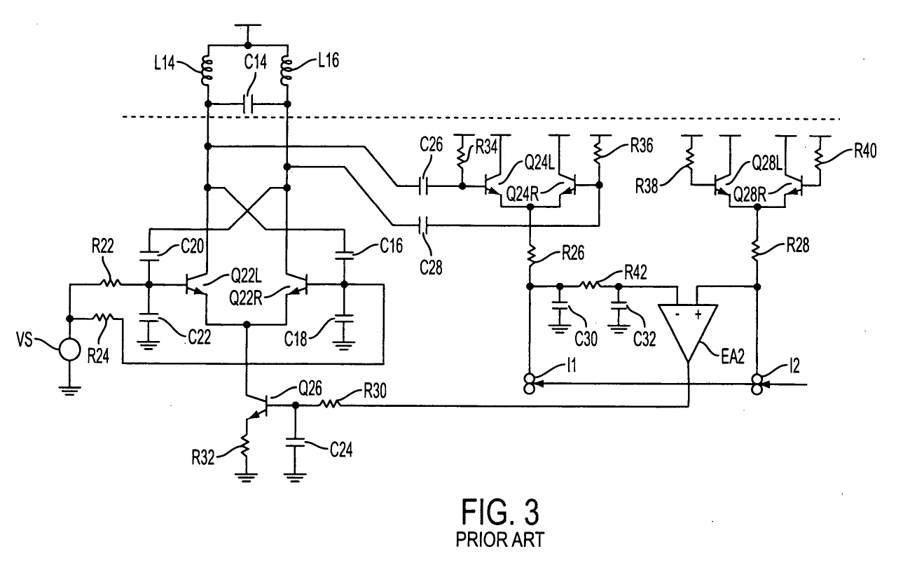

FIG. 4 is an example of a schematic circuit topology of a differential Colpitts oscillator.

FIGS. 5A and 5B are examples of generic topologies of Colpitts and Clapp oscillators.

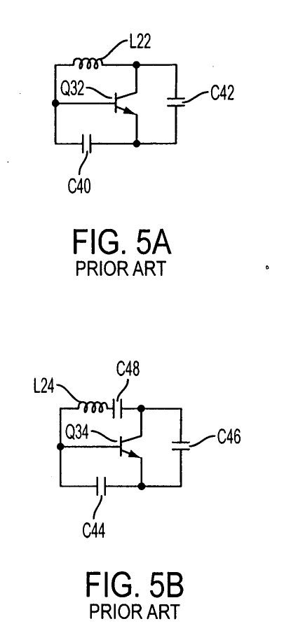

FIG. 6 is an example of a schematic circuit topology of an oscillator according to one embodiment of the disclosure.

FIG. 7 is an example of a schematic circuit topology of an automatic gain control (AGC) block according to one embodiment of the disclosure.

FIG. 8 is an example of a schematic circuit topology of an oscillator with increased tank energy according to another embodiment of the disclosure.

FIG. 9 is an example of a schematic circuit topology of an oscillator according to still another embodiment of the disclosure.

FIG. 10 is an example of a schematic circuit topology of an oscillator according to still another embodiment of the disclosure.

FIG. 11 is an example of a schematic circuit topology of an oscillator providing voltage control frequency tuning according to a further embodiment of the disclosure.

As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### DESCRIPTION OF THE EMBODIMENT

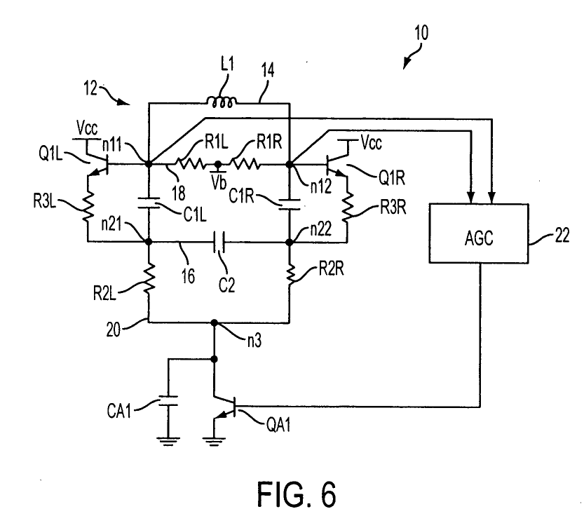

FIG. 6 is one exemplary circuit topology of an oscillator, which is a differential, common-collector (voltage follower) improvement of a Colpitts oscillator. Oscillator 10 in FIG. 6 comprises npn transistor QA1 coupled to a reference voltage source, for example, ground in this embodiment. Transistor QA1 may be a bipolar transistor, MOSFET or JFET.

A differential transistor pair of npn transistors Q1L, Q1R may comprise emitter followers coupled between transistor QA1 and another reference voltage source, for example, a positive supply voltage Vcc in this example. A tail current of the differential pair is driven by transistor QA1. In this topology, negative resistances are implemented by the emitter followers. Transistors Q1L, Q1R may be replaced by MOSFETs or JFETs source followers, or any similar voltage follower.

Oscillator 10 further includes reactive network 12 coupled between the bases of transistor Q1L, Q1R through nodes n 11, n 12, respectively. Reactive network 12 constitutes a tank or resonator of oscillator 10. The network comprises inductance network 14 and capacitance network 16. Inductance network 14 may include a single inductor unit L1 coupled between the bases of transistors Q1L, Q1R. Capacitance network 16 may include capacitors C1L, C1R and C2, and is coupled between the bases of transistors Q1L, Q1R. Capacitor C1L is coupled between nodes n11 and n21. Capacitor C1R is coupled between nodes n12 and n22. Capacitor C2 is coupled between nodes n21 and n22.

The emitters of transistors Q1L, Q1R are connected to degeneration resistors R3L, R3R, respectively. Resistors R3L, R3R are small in resistance, and provide a slight degeneration of the transistors to lower noise that the transistors inject. Resistors R3L, R3R are optional, and the emitters of transistors Q1L, Q1R may be short-circuited to nodes n21, n22, respectively.

Resistance network 18 may be coupled between the bases of transistors Q1L, Q1R and in parallel with inductance network 14 and capacitance network 16. Resistance network 18 may include a pair of resistors R1L, R1R for applying a bias voltage to the bases of transistors Q1L, Q1R. In FIG. 6, the bias voltage is supplied to transistors Q1L, Q1R through node Vb between resistors R1L, R1R.

Oscillator 10 may include another resistor network 20 having resistors R2L, R2R coupled between nodes n21 and n22. Node n3 is provided between resistors R2L, R2R, to which the collector of transistor QA1 is coupled.

The voltage followers of FIG. 6 provide current gain that enables oscillator 10 to oscillate. It should be noted that once a sizable oscillation amplitude is reached, the voltage follower transistors Q1L, Q1R are typically in discontinuous conduction. While this is unusual for voltage followers, the term “voltage followers” still applies because that is what they are doing while conducting current. An output of oscillator 10 may be taken from either the bases or emitters of transistors Q1L, Q1R.

Automatic gain control (“AGC”) block 22 drives the base of transistor QA1 to control the tail current of the differential pair. AGC block 22 receives inputs from nodes n11 and n12, i.e., base voltages of transistors Q1L and Q1R (tank voltage). For example, AGC block 22 increases the tail current of the differential pair when the tank voltage is low, and decreases the tail current when the tank voltage is high. AGC block 22 is an amplitude controller.

Noise bypass capacitor CA1 is coupled between the collector of transistor QA1 and ground in this embodiment. Capacitor CA1 may have 1,000 to 10,000 pF for this example. Capacitor CA1 not only filters a loop response of AGC block 22, but also filters noise of AGC block 22 and active devices in the topology.

The elements of oscillator 10 may be formed on a single chip. However, inductor unit L1 and capacitor CA1 can be off-chip.

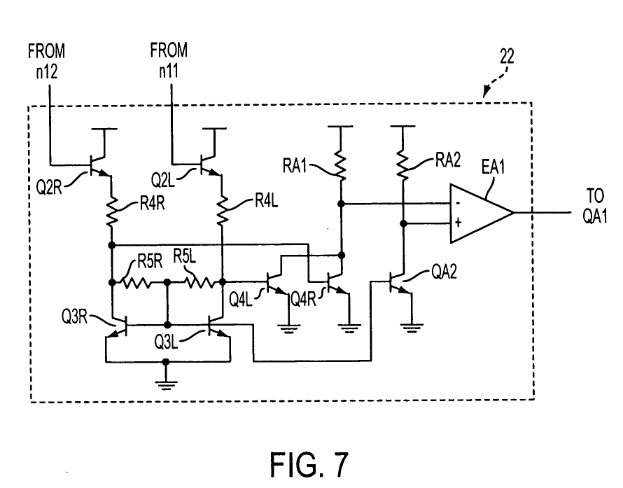

In the exemplary circuit topology of FIG. 7, AGC block 22 includes emitter followers (transistors Q2L, Q2R and resistors R4L, R4R), a differential amplifier (transistors Q3L, Q3R, resistors R5L, R5R), a level sensor (transistor Q4L, Q4R, QA2 resistor RA1, RA1) and an error amplifier EA1. The emitter followers provide a low noise sensing of the differential tank voltages, provided that the emitter followers are appropriately biased, typically by a very small collector current. The differential amplifier creates a drive voltage necessary for the level sensor. The common base point of transistors Q3L, Q3R is used to bias transistor QA2. The collector current of transistor QA2 imitates the average of the collector currents of transistors Q3L, Q3R. The base-collector resistors R5L, R5R create base drive voltages for transistors Q4L, Q4R in the level sensor. With resistors R4L, R4R smaller than that of resistors R3L, R3R, the base drive voltages to transistors Q4L, Q4R are scaled down version of the tank voltages swinging about the level of the base drive voltage of transistor QA2. Because the collector currents of transistors Q4L, Q4R respond in an exponential fashion to the base voltage of the transistors, any non-zero level of the tank voltage creates an average collector current of transistors Q4L, Q4R that is greater than that with zero tank voltage.

Although resistors RA1, RA2 are shown connected to the same reference voltage source as the collectors of transistors Q2L, Q2R, those skilled in the art will recognize that they can be connected to any common point with sufficient headroom. For example, the common point may actively be driven to stabilize the common mode input level to error amplifier EA1.

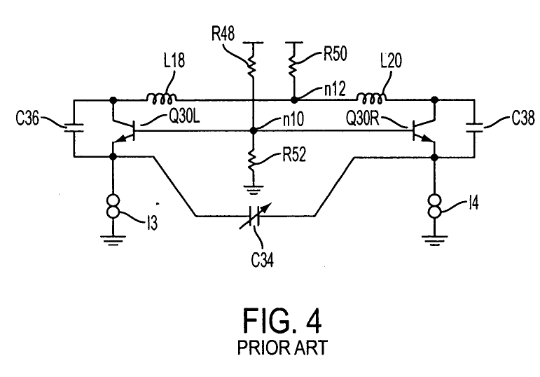

By properly scaling transistors QA2, Q4L, Q4R and resistors RA1, RA2 for minimum thermal drift, the level sensor can feed error amplifier EA1 with a signal that is, on average, zero only with the desired, well-controlled tank voltage swing. Another way to correct for thermal drift associated with the responses of transistor Q4L, Q4R is to connect resistors RA1 and RA2 to different voltages, and for example, this may be done with a Thevenin equivalent, by connecting a third resistor (not shown) from transistor QA2's collector to ground. Unlike the AGC shown in, for example, FIG. 4, AGC block 22 can be configured to allow large tank voltages, limited only by the power supply imposed headroom restraints in the oscillator. The swing can be well in excess of a single BJT collector-emitter saturation voltage and even in excess of a base-emitter bias voltage.

Returning to FIG. 6, oscillator 10 operates from positive supply voltage Vcc, connected to the collectors of transistors Q1L, Q1R, the return connected to the emitter of transistor QA1. The differential pair allows large voltage swings on the tank, which minimizes phase noise. The voltage at node Vb between resistors R1L and R1R may preferably be about two thirds in magnitude of the voltage of positive supply voltage Vcc. This allows the tank voltages on the bases of transistors Q1L, Q1R to swing a peak to peak voltage of approximately two thirds the magnitude of positive supply voltage Vcc. A differential peak to peak swing on the tank is then greater than positive supply voltage Vcc. By providing large tank energy, phase noise is lowered significantly.

With common-collector (voltage follower) topology, a DC bias must be given the bases of transistors Q1L, Q1R. This is advantageous, as a base current required is typically two decades lower than an emitter or collector current. Thus, feed resistors R1L, R1R can be two decades larger in resistance. By using feed resistors R1L, R1R, an upper limit is placed on the effective resonator Q, but with the large values acceptable in the bases, this limitation is not detrimental because with real inductors and capacitors, the Q will be an order of magnitude or so lower.

Noise that may be contributed by transistor QA1 can be filtered by capacitor CA1. Accordingly, the only bias noise in the core of oscillator 10 may be generated by resistors R2L, R2L. For a given current level, resistors usually have less noise than a transistor based current source. In addition, the series combination of resistors R2L and R2R limits the effective resonator Q. However, because capacitor C2 typically carries a fraction of the voltage that capacitors C1L, C1R do in a well designed Colpitts oscillator, the values of resistors R2L, R2R may be lower before they become a significant contributor to noise relative to the values of feed resistors R1L, R1R.

In the circuit of FIG. 7, if the voltage at node Vb is made about three times the bandgap voltage of transistors Q2L, Q2R, the voltages across resistors R4L, R4R would be approximately proportional to absolute temperature (PTAT), as would the differential sensor drive from resistors R5L, R5R.

AGC block 22 shown in FIG. 7 is optimized for a supply voltage of 5V for this example. For a 3.3V supply voltage, it may be advantageous to make the voltage at node Vb two times the bandgap voltage, which in both cases are easy to implement and are temperature stable.

Error amplifier EA1 may be constructed of slow devices, such as lateral PNP transistors because an AGC loop bandwidth should be substantially lower in frequency than the oscillation. To keep such an error amplifier from suffering non-linear effects, a small, on-chip, capacitor can be used to filter the collector voltage of transistors Q4L, Q4R. Alternatively, resistors RA1, RA2 and filter capacitors can be included into error amplifier EA1 that operates on the current difference of the sensor collector current signals. To filter the high frequency ripple of transistors Q4L, Q4R, a Miller compensation capacitor from that node to the collector of QA1 can be used. For high resonator Qs, it may aid stability of the amplitude control to replace such a capacitor with a lead-lag network consisting of one small capacitor in parallel with the series connection of a larger capacitor and a resistor, as is familiar to those skilled in the art.

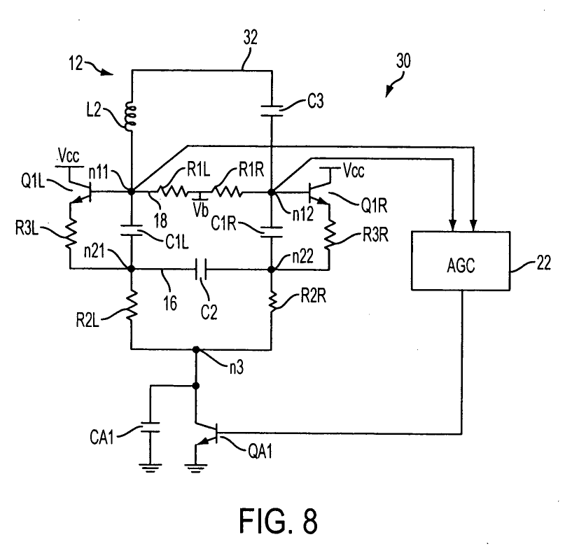

FIG. 8 illustrates another improved oscillator circuit topology. Oscillator 30 in FIG. 8 illustrates a Clapp configuration, including L-C network 32 replacing inductance network 14 shown in FIG. 6. Except for L-C network 32, the topology of the circuit illustrated in FIG. 8 is substantially the same as that in FIG. 6. L-C network 32, i.e., a Clapp extension, includes serially-connected single inductor unit L2 and single capacitor C3 coupled between the bases of transistors Q1L, Q1R through nodes n11 and n12, respectively. Like inductance network 12 in FIG. 6, L-C network 32 may be off chip.

Because of feed resistors R1L, R1R, a DC path between the two sides of the differential resonator is not required external to the device. Internal to the chip, the circuit operates differentially. L-C network 32 of the Clapp extension allows the tank energy to be increased to lower phase noise, as well as providing a second resonator element to center the design using standard value inductors.

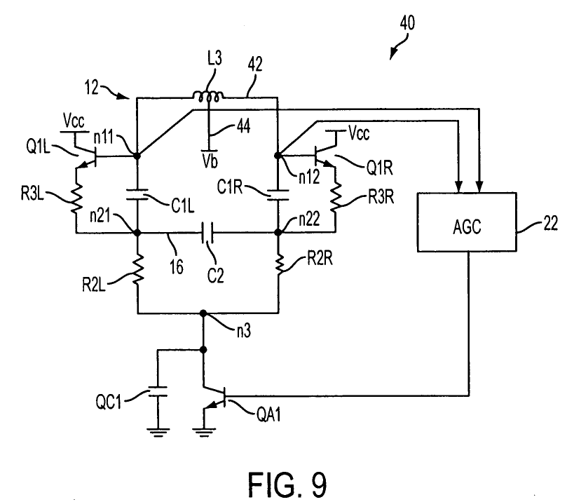

FIG. 9 illustrates a further example of an oscillator. Oscillator 40 in FIG. 9 includes inductance network 42 replacing inductance network 14 shown in FIG. 6. Feed resistors R1L, R1R are also eliminated, and inductor L1 is replaced by center-tapped inductor L3. Center tap 44 can be tied to node Vb, which provides the DC base bias of transistors Q1L, Q1R.

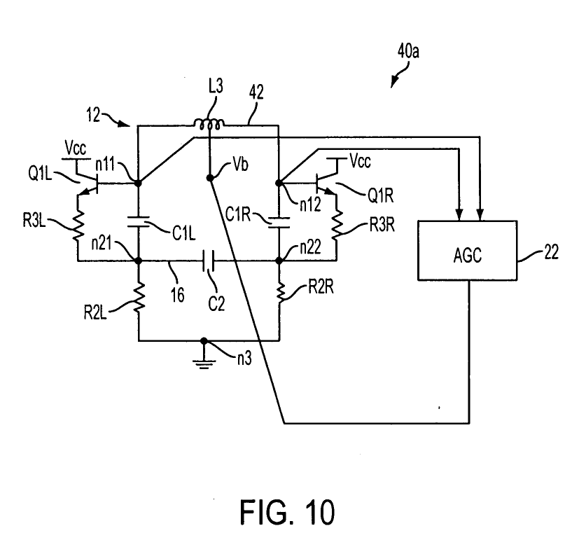

As shown in FIG. 10, for example, transistor QA1 and capacitor QC1 may be eliminated from oscillator 40. In oscillator 40a of FIG. 10, AGC block 22 may be connected to node Vb to control the bias voltage.

AGC noise reduction capacitor CA1 is connected to the power supply return. However, it may be advantageous to bypass capacitor CA1 to some other AC ground. For instance, node Vb; this could be particularly advantageous with the center-tapped inductor configuration of FIG. 9.

Lower phase noise in this embodiment can be attributed to several factors. (1) External noise bypass capacitor CA1 not only filters a loop response of AGC block 22, but also filters noise of AGC block 22 and active devices in the topology. (2) No active devices are coupled between external noise bypass capacitor CA1 and the differential pair, and resistors R2L, R2R biasing the differential pair have lower noise than that of active devices, for the same power and headroom (swing). (3) Large tank energy lowers phase noise. The tank energy can be enhanced by the differential pair with the pair of resistors R1L, R1R coupled between the bases of transistors Q1L, Q1R (see FIGS. 6 and 8), AGC block 22, and the Clapp extension (see FIG. 8).

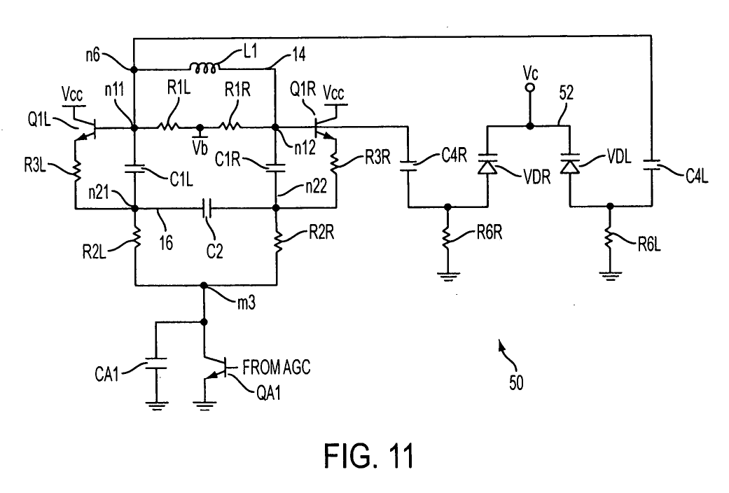

Oscillators 10, 30, 40 and 40a shown in FIGS. 6 and 8-10 are fixed frequency oscillators. Alternatively, a varactor network may be incorporated into those oscillators to create a voltage controlled oscillator (VCO). FIG. 11 is an example of a VCO. As an example, VCO 50 in FIG. 11 is formed by incorporating varactor network 52 into oscillator 10 of FIG. 6. Varactor network 52 can be applied to oscillators 30, 40 and 40a of FIGS. 8-10.

Coupling capacitors C4L, C4R connect the varactor network to the tank in parallel with inductor network 14 and capacitor network 16. Varactors VDL, VDR are connected between coupling capacitors C4L, C4R. Resistors R6L, R6R may couple varactor network 52 to ground in this example. DC control voltage Vc varies capacitance of varactors VDL, VDR. For example, when DC control voltage Vc is increased, varactor capacitances decrease, and the oscillator frequency increases.

Having described embodiments, it is noted that modifications and variations can be made by person skilled in the art in light of the above teachings. For example, transistor QA1 and capacitor CA1 may be eliminated from the oscillator shown in FIG. 6. In such a case, node n3 may be grounded, and the output of AGC block 22 may be supplied to node Vb between resistors R1L, R1R (cf. FIG. 10). Moreover, AGC block 22 may also be eliminated in some circumstances.

There are many alternative ways to couple a varactor network to the oscillator, such as single varactor topologies, or a common-anode version of the common-cathode configuration shown in FIG. 11. Furthermore, the varactor network connection is not restricted to that shown in FIG. 11, but may be connected to the resonator in many different ways such as, for example, just across C2 (cf. FIG. 4).

Resistors R6L, R6R in FIG. 11 could alternatively be inductors or combinations of resistors and inductors. A single inductor with a center-tap could also be used. Such changes could reduce or eliminate the noise contributed by resistor R6L, R6R.

Another variation would be to use all PNP or PMOS transistors in which case one of the reference voltage sources (Vcc) would need to be a negative voltage relative to another reference voltage source (ground).

Finally, the oscillation signal can be taken from the differential or single-ended voltages present, but could also be taken from the currents of the voltage followers. For instance, in FIGS. 6, 8, 9, 10 or 11, the collectors of transistors QL1 and Q1R could be connected to Vcc indirectly, such as through sense resistors or cascode transistors. In such a case, the collector currents create a differential output signal, but transistors QL1 and Q1R are still functioning as voltage followers in the oscillator. Additionally, the signal used to create the output timing reference need not be the same one used to sense the oscillation voltage level for amplitude control. For instance, in one such combination, the collector currents of transistors Q1L, Q1R could be used to create the output timing signal, but the AGC could act upon the oscillation voltage across capacitor C2.

It is therefore to be understood that changes may be made in the particular embodiments disclosed that are within the scope and sprit of the disclosure as defined by the appended claims and equivalents.

What is claimed is:

1. An oscillator comprising:
a transistor coupled to a first reference voltage source;
a differential transistor pair comprising first and second voltage followers coupled between a second reference voltage source and the transistor;
a reactive network coupled between control electrodes of the first and second voltage followers; and
a resistance network coupled between the control electrodes and in parallel with the reactive network.

2. The oscillator according to claim 1, wherein the resistance network comprises a pair of resistors for applying a bias voltage to the control electrodes of the first and second voltage followers.

3. The oscillator according to claim 2, wherein the bias voltage is about two-thirds of the way from the voltage of the first reference voltage source to the voltage of the second reference voltage source.

4. The oscillator according to claim 1, further comprising a variable capacitance network coupled to the reactive network.

5. The oscillator according to claim 1, wherein the reactive network includes
an inductance coupled between the control electrodes of the first and second voltage followers, and
a capacitance coupled between the control electrodes of the first and second voltage followers.

6. The oscillator according to claim 5, wherein
each of the voltage followers further comprises a first electrode coupled to the transistor, and a second electrode coupled to the second reference voltage source,
the capacitance includes first, second and third capacitors,
the first capacitor is coupled between the control electrode and the first electrode of the first voltage follower,
the second capacitor is coupled between the control electrode and the first electrode of the second voltage follower, and
the third capacitor is coupled between the first electrodes of the first and second voltage followers.

7. The oscillator according to claim 6, further comprising
a first resistor having two terminals, one terminal being coupled to the transistor, and another terminal being coupled to the first electrode of the first voltage follower and one terminal of the third capacitor, and
a second resistor having two terminals, one terminal being coupled to the transistor, and another terminal being coupled to the first electrode of the second voltage follower and another terminal of the third capacitor.

8. The oscillator according to claim 7, further comprising a variable capacitance network coupled to the reactive network.

9. The oscillator according to claim 1, wherein
the reactive network includes an L-C network and a capacitance network,
the L-C network includes a serially-connected inductor and capacitor coupled between the control electrodes of the first and second voltage followers, and
the capacitance network is coupled between the control electrodes of the first and second voltage followers.

10. The oscillator according to claim 9, wherein
each of the voltage followers further comprises a first electrode coupled to the transistor, and a second electrode coupled to the second reference voltage source,
the capacitance network includes first, second and third capacitors,
the first capacitor is coupled between the control electrode and the first electrode of the first voltage follower,
the second capacitor is coupled between the control electrode and the first electrode of the second voltage follower, and
the third capacitor is coupled between the first electrodes of the first and second voltage followers.

11. The oscillator according to claim 10, further comprising
a first resistor having two terminals, one terminal being coupled to the transistor, and another terminal being coupled to the first electrode of the first voltage follower and one terminal of the third capacitor, and
a second resistor having two terminals, one terminal being coupled to the transistor, and another terminal being coupled to the first electrode of the second voltage follower and another terminal of the third capacitor.

12. The oscillator according to claim 11, further comprising a variable capacitance network coupled to the reactive network.

13. The oscillator according to claim 1, further comprising a gain control loop for driving a control electrode of the transistor to control the tail current based on the oscillation voltage level.

14. The oscillator according to claim 1, wherein the transistor includes a first electrode coupled to the first reference voltage source, a second electrode coupled to both first electrodes of the first and second voltage followers,
the oscillator further comprising a capacitor coupled between the second electrode of the first transistor and the first reference voltage source.

15. The oscillator according to claim 14, further comprising a gain control loop for driving a control electrode of the transistor to control the tail current based on the oscillation voltage level.

16. The oscillator according to claim 15, wherein the reactive network includes
an inductance coupled between the control electrodes of the first and second voltage followers, and
a capacitance coupled between the control electrodes of the first and second voltage followers.

17. The oscillator according to claim 16, wherein
each of voltage followers further comprises a first electrode coupled to the transistor, and a second electrode coupled to the second reference voltage source,
the capacitance network includes first, second and third capacitors,
the first capacitor is coupled between the control electrode and the first electrode of the first voltage follower,
the second capacitor is coupled between the control electrode and the first electrode of the second voltage follower, and
the third capacitor is coupled between the first electrodes of the first and second voltage followers.

18. The oscillator according to claim 17, further comprising
a first resistor having two terminals, one terminal being coupled to the transistor, and another terminal being coupled to the first electrode of the first voltage follower and one terminal of the third capacitor, and
a second resistor having two terminals, one terminal being coupled to the transistor, and another terminal being coupled to the first electrode of the second voltage follower and another terminal of the third capacitor.

19. The oscillator according to claim 18, further comprising a variable capacitance network coupled to the reactive network.

20. The oscillator according to claim 15, wherein
the reactive network includes an L-C network and a capacitance network,
the L-C network includes a serially-connected inductor and capacitor coupled between the control electrodes of the first and second voltage followers, and
the capacitance network is coupled between the control electrodes of the first and second voltage followers.

21. The oscillator according to claim 20, wherein
each of voltage followers further comprises a first electrode coupled to the transistor, and a second electrode coupled to the second reference voltage source,
the capacitance network includes first, second and third capacitors,
the first capacitor is coupled between the control electrode and the first electrode of the first voltage follower,
the second capacitor is coupled between the control electrode and the first electrode of the second voltage follower, and
the third capacitor is coupled between the first electrodes of the first and second voltage followers.

22. The oscillator according to claim 21, further comprising
a first resistor having two terminals, one terminal being coupled to the transistor, and another terminal being coupled to the first electrode of the first voltage follower and one terminal of the third capacitor, and
a second resistor having two terminals, one terminal having coupled to the transistor, and another terminal being coupled to the first electrode of the second voltage follower and another terminal of the third capacitor.

23. The oscillator according to claim 22, further comprising a variable capacitance network coupled to the reactive network.

24. The oscillator according to claim 1, further comprising degeneration resistors respectively coupled to the first electrodes of the first and second voltage followers.

25. An oscillator comprising:
a transistor coupled to a first reference voltage source;
a differential transistor pair comprising first and second voltage followers coupled between a second reference voltage source and the transistor;
a capacitance network coupled between control electrodes of the first and second voltage followers; and
an inductor coupled between the control electrodes of the first and second voltage followers, and having a center tap coupled to a third reference voltage source.

26. The oscillator according to claim 25, further comprising a variable capacitance network coupled to the capacitance network.

27. The oscillator according to claim 25, wherein
each of voltage followers further comprising a first electrode coupled to the transistor, and a second electrode coupled to the second reference voltage source, and
the capacitance network includes first, second and third capacitors,
the first capacitor is coupled between the control electrode and the first electrode of the first voltage follower,
the second capacitor is coupled between the control electrode and the first electrode of the second voltage follower, and
the third capacitor is coupled between the first electrodes of the first and second voltage followers.

28. The oscillator according to claim 27, further comprising
a first resistor having two terminals, one terminal being coupled to the transistor, and another terminal being coupled to the first electrode of the first voltage follower and one terminal of the third capacitor, and
a second resistor having two terminals, one terminal being coupled to the transistor, and another terminal being coupled to the first electrode of the second voltage follower and another terminal of the third capacitor.

29. The oscillator according to claim 25, further comprising a gain control loop for driving a control electrode of the transistor to control the tail current based on the oscillation voltage level.

30. The oscillator according to claim 25, wherein the transistor includes a first electrode coupled to the first reference voltage source, a second electrode coupled to both the first electrodes of the first and second voltage followers,
the oscillator further comprising a capacitor coupled between the second electrode of the first transistor and the first reference voltage source.

31. The oscillator according to claim 30, further comprising a gain control loop for driving a control electrode of the transistor to control the tail current based on the oscillation voltage level.

32. The oscillator according to claim 31, further comprising a variable capacitance network coupled to the capacitance network.

33. The oscillator according to claim 25, further comprising degeneration resistors respectively coupled to the first electrodes of the first and second voltage followers.

34. An oscillator comprising:
a differential transistor pair including first and second transistors each having a control electrode, a first electrode and a second electrode, the first electrode of each transistor being coupled to a first reference voltage source, the second electrodes of the first and second transistors being coupled to each other through a first resistance network, and the first resistance network being coupled to a second reference voltage source;
a second resistance network coupled between the control electrodes of the first and second transistors;
a reactance network coupled between the control electrodes of the first and second transistors; and
a capacitance network coupled between the control electrodes of the first and second transistors.

35. The oscillator according to claim 34, wherein the second resistance network comprises a pair of resistors for applying a bias voltage to the control electrodes of the first and second transistors.

36. The oscillator according to claim 35, wherein the bias voltage is about two-thirds of the way from the voltage of the second reference voltage source to the voltage of the first reference voltage source.

37. The oscillator according to claim 34, further comprising a variable capacitance network coupled to the reactance network.

38. The oscillator according to claim 34, wherein the reactance network includes inductance only.

39. The oscillator according to claim 34, wherein the reactance network includes a serially-connected inductor and capacitor coupled between the control electrodes of the first and second transistors.

40. The oscillator according to claim 34, wherein
the capacitance network includes first, second and third capacitors,
the first capacitor is coupled between the control electrode and the second electrode of the first transistor,
the second capacitor is coupled between the control electrode and the second electrode of the second transistor, and
the third capacitor is coupled between the second electrodes of the first and second transistors.

41. The oscillator according to claim 40, wherein
the first resistance network includes first and second resistors,
one terminal of the first resistor is coupled to one end of the third capacitor and the second electrode of the first transistor,
one terminal of the second resistor is coupled another end of the third capacitor and the second electrode of the second transistor, and
the other terminals of the first and second resistors are commonly coupled to the second reference voltage source.

42. The oscillator according to claim 34, further comprising a third transistor having a control electrode, a first electrode and a second electrode, the first electrode being coupled to the first resistance network, the second electrode being coupled to the second reference voltage source, the third transistor configured for driving a tail current of the differential transistor pair in accordance with a voltage applied to the third transistor control electrode.

43. The oscillator according to claim 42, further comprising a gain control loop for driving the control electrode of the third transistor based on the oscillation voltage level.

44. The oscillator according to claim 43, further comprising a capacitor coupled between the first electrode of the third transistor and the second reference voltage source.

45. The oscillator according to claim 34, further comprising degeneration resistors respectively coupled to the second electrodes of the first and second transistors.

46. The oscillator according to claim 34, further comprising a gain control loop for controlling a bias voltage of the control electrodes of the first and second transistors based on the oscillation voltage level.

47. The oscillator according to claim 34, wherein
the differential transistor pair, the first and second resistance networks, and the capacitance network are formed on a common chip, and
the reactance network is externally coupled between the control electrodes of the first and second transistors.

48. An oscillator comprising:
a differential transistor pair including first and second transistors each having a control electrode, a first electrode and a second electrode, the first electrodes of each transistor being coupled to a first reference voltage source, the second electrodes of the first and second transistors being coupled to each other through a resistance network, and the resistance network being coupled to a second reference voltage source;
an inductor coupled between the control electrodes of the first and second transistors, and having a center tap coupled to a third reference voltage source; and
a capacitance network coupled between the control electrodes of the first and second transistors.

49. The control oscillator according to claim 48, further comprising a variable capacitance network coupled to the capacitance network.

50. The oscillator according to claim 48, wherein
the capacitance network includes first, second and third capacitors,
the first capacitor is coupled between the control electrode and the second electrode of the first transistor,
the second capacitor is coupled between the control electrode and the second electrode of the second transistor, and
the third capacitor is coupled between the second electrodes of the first and second transistors.

51. The oscillator according to claim 50, wherein
the resistance network comprises first and second resistors,
one terminal of the first resistor is coupled to one terminal of the third capacitor and the second electrode of the first transistor,
one terminal of the second resistor is coupled to another terminal of the third capacitor and the second electrode of the second transistor, and
the other terminals of the first and second resistors are commonly coupled to the second reference voltage source.

52. The oscillator according to claim 48, further comprising a third transistor having a control electrode, a first electrode and a second electrode, the first electrode being coupled to the resistance network, the second electrode being coupled to the second reference voltage source, the third transistor configured for driving a tail current of the differential transistor pair in accordance with a voltage applied to the third transistor control electrode.

53. The oscillator according to claim 52, further comprising a gain control loop for driving the control electrode of the third transistor based on the oscillation voltage level.

54. The oscillator according to claim 53, further comprising a capacitor coupled between the first electrode of the third transistor and the second reference voltage source.

55. The oscillator according to claim 48, further comprising degeneration resistors respectively coupled to the second electrodes of the first and second transistors.

56. The oscillator according to claim 48, further comprising a gain control loop for controlling the bias voltage based on the oscillation voltage level.

57. The oscillator according to claim 48, wherein
the differential transistor pair, the resistance network and the capacitance network are formed on a common chip, and
the center-tapped inductor is externally coupled between the control electrodes of the first and second transistors.

58. An oscillator comprising:
a differential transistor pair comprising first and second voltage followers each having first and second electrodes respectively coupled to first and second reference voltage sources;
a reactive network coupled between control electrodes of the first and second voltage followers;
a resistance network coupled between the control electrodes and in parallel with the reactive network; and
an amplitude control loop for controlling a bias level of the first and second voltage followers.

59. The oscillator according to claim 58, further comprising a variable capacitance network coupled to the reactive network.

60. The oscillator according to claim 58, wherein the resistance network comprises a pair of resistors for applying the bias voltage to the first and second transistors.

61. The oscillator according to claim 60, wherein the bias voltage is about two-thirds of the way from the voltage of the first reference voltage source to the voltage of the second reference voltage source.

62. The oscillator according to claim 58, wherein the reactance network includes
an inductor coupled between the control electrodes of the first and second voltage followers; and
a capacitance network coupled between the control electrodes of the first and second voltage followers and in parallel with the inductor.

63. The oscillator according to claim 62, wherein
the capacitance network includes first, second and third capacitors,
the first capacitor is coupled between the control electrode and the second electrode of the first voltage follower,
the second capacitor is coupled between the control electrode and the second electrode of the second voltage follower, and
the third capacitor is coupled between the second electrodes of the first and second voltage followers.

64. The oscillator according to claim 63, further comprising:
a first resistor having two terminals, one terminal being coupled to one end of the third capacitor and the second electrode of the first voltage follower; and
a second resistor having two terminals, one terminal being coupled to another end of the third capacitor and the second electrode of the second voltage follower, wherein
the other terminals of the first and second resistors are commonly coupled to the second reference voltage source.

65. The oscillator according to claim 58, wherein the reactance network includes
a serially-connected inductor and capacitor coupled between the control electrodes of the first and second voltage followers; and
a capacitance network coupled between the control electrodes of the first and second voltage followers and in parallel with the serially-connected inductor and capacitor.

66. The oscillator according to claim 65, wherein
the capacitance network includes first, second and third capacitors,
the first capacitors is coupled between the control electrode and the second electrode of the first voltage follower,
the second capacitor is coupled between the control electrode and the second electrode of the second voltage follower, and
the third capacitor is coupled between the second electrodes of the first and second voltage followers.

67. The oscillator according to claim 66, further comprising:
a first resistor having two terminals, one terminal being coupled to one end of the third capacitor and the second electrode of the first voltage follower; and
a second resistor having two terminals, one terminal being coupled to another end of the third capacitor and the second electrode of the second voltage follower, wherein
the other terminals of the first and second resistors are commonly coupled to the second reference voltage source.

68. The oscillator according to claim 58, further comprising degeneration resistors respectively coupled to the second electrodes of the first and second voltage followers.

69. An oscillator comprising:
a differential transistor pair comprising first and second voltage followers each having first and second electrodes respectively coupled to first and second reference voltage sources;
a capacitance network coupled between control electrodes of the first and second voltage followers;
an inductor coupled between the control electrodes of the first and second voltage followers, and having a center tap; and
an amplitude control loop for controlling a bias level of the first and second voltage followers.

70. The oscillator according to claim 69, further comprising a variable capacitance network coupled to the capacitance network.

71. The oscillator according to claim 69, wherein
the capacitance network includes first, second and third capacitors,
the first capacitor is coupled between the control electrode and the second electrode of the first voltage follower,
the second capacitor is coupled between the control electrode and the second electrode of the second voltage follower, and
the third capacitor is coupled between the second electrodes of the first and second voltage followers.

72. The oscillator according to claim 71, further comprising
a resistance network including first and second resistors, wherein
one terminal of the first resistor is coupled to one end of the third capacitor and the second electrode of the first voltage follower,
one terminal of the second resistor is coupled to another end of the third capacitor and the second electrode of the second voltage follower, and
the other terminals of the first and second resistors are commonly coupled to the second reference voltage source.

73. The oscillator according to claim 69, further comprising degeneration resistors respectively coupled to the second electrodes of the first and second voltage followers.
